(19) United States
(12) Patent Application Publication
(10) Pub. No.: US 2017/0327941 A1
(43) Pub. Date: Nov. 16, 2017

(54) SPUTTERING APPARATUS AND METHOD OF FORMING A LAYER USING THE SAME

(71) Applicant: Samsung Electronics Co., Ltd., Suwon-si (KR)

(72) Inventors: Woo-Jin KIM, Yongin-si (KR); Ki-Woong KIM, Hwaseong-si (KR); Joon-Myoung LEE, Anyang-si (KR)

(21) Appl. No.: 15/395,016

(22) Filed: Dec. 30, 2016

(30) Foreign Application Priority Data
May 10, 2016 (KR) 10-2016-0057142

(51) Int. Cl. C23C 14/34; C23C 14/08; C23C 14/35

(52) U.S. Cl. CPC C23C 14/3464; C23C 14/352; C23C 14/081; C23C 14/345

(57) ABSTRACT

A sputtering apparatus includes a chamber configured to provide a space where a deposition process is performed on a substrate, a substrate holder configured to support the substrate within the chamber, and at least one turret-type target assembly located over the substrate, including a plurality of targets mounted thereon and adapted to operatively rotate by a predetermined angle about its longitudinal axis such that any one of the targets is off-axis aligned with respect to a film-deposited surface of the substrate.

### PRIORITY STATEMENT

This application claims the benefit of priority under 35 U.S.C. §119 to Korean Patent Application No. 10-2016-0057142, filed on May 10, 2016, in the Korean Intellectual Property Office (KIPO), the contents of which are herein incorporated by reference in their entirety.

### BACKGROUND

### 1. Field

Example embodiments relate to a sputtering apparatus and a method of forming a layer using the same. More particularly, example embodiments relate to a sputtering apparatus for depositing a thin film on a wafer and a method of forming a layer using the same.

### 2. Description of the Related Art

A sputtering apparatus may be used for performing a physical vapor deposition process. For example, the sputtering apparatus may be used to deposit a thin film for forming a magnetic tunnel junction (MTJ) structure of a magnetoresistive random access memory (MRAM) device.

In related arts, as a deposition rate of the sputtering apparatus is increased, many targets may be required or the target may be consumed much more rapidly, and periods between preventive maintenance may be reduced due to particles deposited within a chamber, resulting in more frequent preventive maintenance.

### SUMMARY

In some aspects, the disclosure is directed to a sputtering method comprising: placing a substrate in a chamber configured to provide a space where a deposition process is performed on the substrate; supporting the substrate within the chamber using a substrate holder; and performing a sputtering process using a turret-type target assembly located over the substrate, wherein the turret-type target assembly includes a plurality of targets mounted thereon and adapted to operatively rotate by a predetermined angle about a longitudinal axis such that at least one of the plurality of targets is off-axis aligned with respect to a film-deposited surface of the substrate.

In some aspects, the disclosure is directed to a sputtering method comprising: placing a substrate in a deposition chamber; supporting the substrate within the deposition chamber using a substrate holder; and performing a sputtering process using at least one turret-type target assembly located over the substrate, wherein the at least one turret-type target assembly includes a plurality of targets mounted on outer surfaces thereof and adapted to operatively rotate by a predetermined angle about a longitudinal axis such that at least one of the plurality of targets is off-axis aligned with respect to a film-deposited surface of the substrate.

In some aspects, the disclosure is directed to a sputtering method comprising: placing a substrate in a deposition chamber; supporting the substrate within the deposition chamber using a substrate holder; and performing a sputtering process using a turret-type target assembly located above the substrate, wherein the turret-type target assembly comprises a support body having a plurality of target mounting surfaces, a plurality of targets each mounted on a corresponding one of the plurality target mounting surfaces, wherein the turret-type target assembly does not overlap the substrate when viewed in a plan view, and wherein the turret-type target assembly is adapted to rotate by a predetermined angle about a longitudinal axis of the turret-type target assembly such that at least one of the plurality of targets faces a film-deposited surface of the substrate at an oblique angle.

Thus, a preventive maintenance period of the sputtering apparatus may be increased and layer thickness uniformity in a wafer plane may be improved. Additionally, particles within a chamber may be prevented from being generated, and an overall size of the deposition chamber may be decreased and unit per equipment hour (UPEH) may be increased.

### BRIEF DESCRIPTION OF THE DRAWINGS

Example embodiments will be more clearly understood from the following detailed description taken in conjunction with the accompanying drawings.

FIGS. 1 to 15 represent non-limiting, example embodiments as described herein.

FIG. 1 is a perspective view illustrating a sputtering apparatus in accordance with example embodiments.

FIG. 2 is a plan view illustrating the sputtering apparatus in FIG. 1.

FIG. 3 is a perspective view illustrating a turret-type target assembly of the sputtering apparatus in FIG. 1.

FIG. 4 is a cross-sectional view taken along the line A-A′ in FIG. 3.

FIG. 5 is a cross-sectional view taken along the line B-B′ in FIG. 3.

FIG. 6 is a cross-sectional view illustrating a rotation operation of the turret-type target assembly in FIG. 3.

FIG. 7 is a plan view illustrating a sputtering apparatus in accordance with example embodiments.

FIG. 8 is a plan view illustrating a sputtering apparatus in accordance with example embodiments.

FIG. 9 is a perspective view illustrating a turret-type target assembly of the sputtering apparatus in FIG. 8.

FIGS. 10A to 10D are cross-sectional views illustrating turret-type target assemblies in accordance with example embodiments.

FIG. 11 is a flow chart illustrating a method of depositing a layer in accordance with example embodiments.

FIGS. 12 to 15 are cross-sectional views illustrating a method of manufacturing an MRAM device in accordance with example embodiments.

### DETAILED DESCRIPTION OF EXAMPLE EMBODIMENTS

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Also these spatially relative terms such as “above” and “below” as used herein have their ordinary broad meanings—for example element A can be above element B even if when looking down on the two elements there is no overlap between them (just as something in the sky is generally above something on the ground, even if it is not directly above).

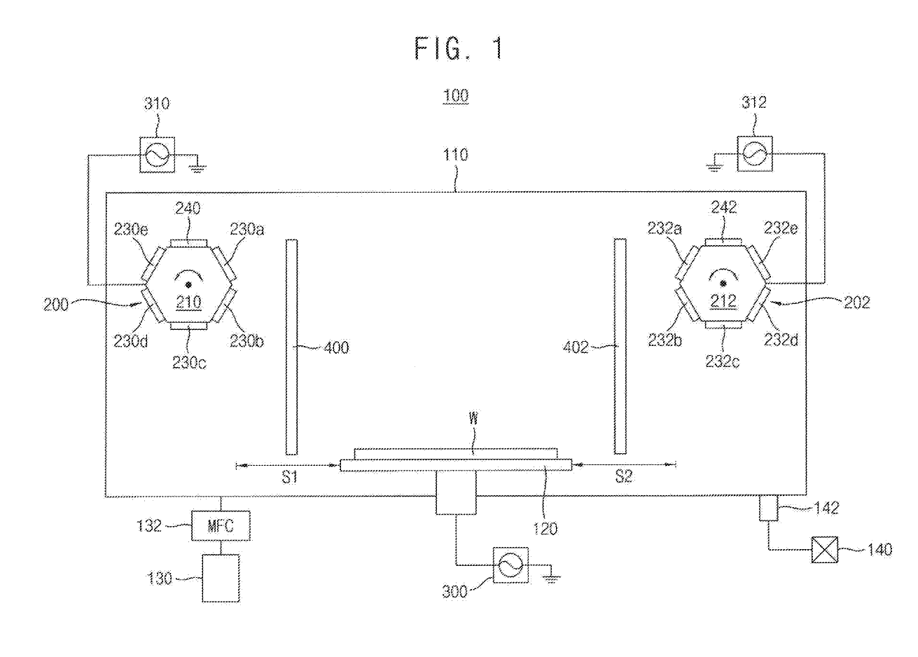

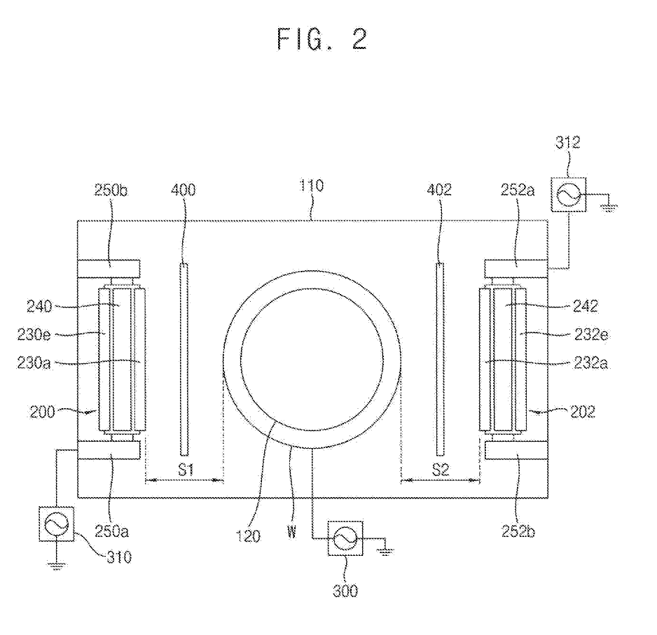

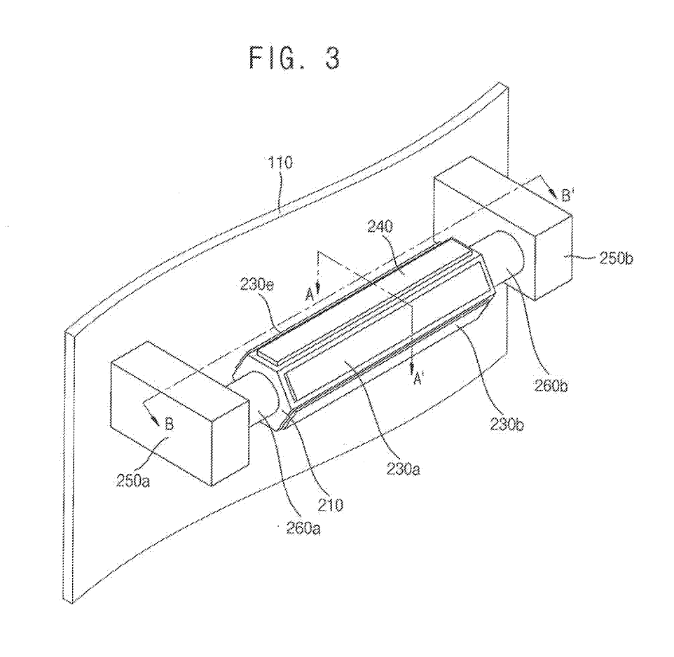

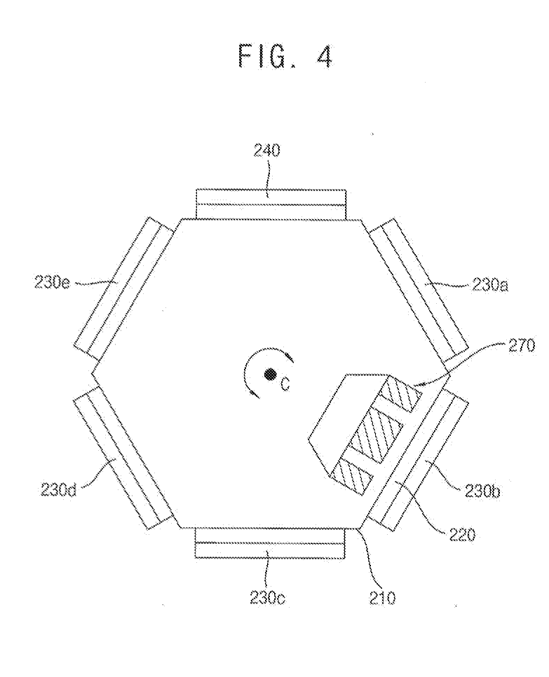

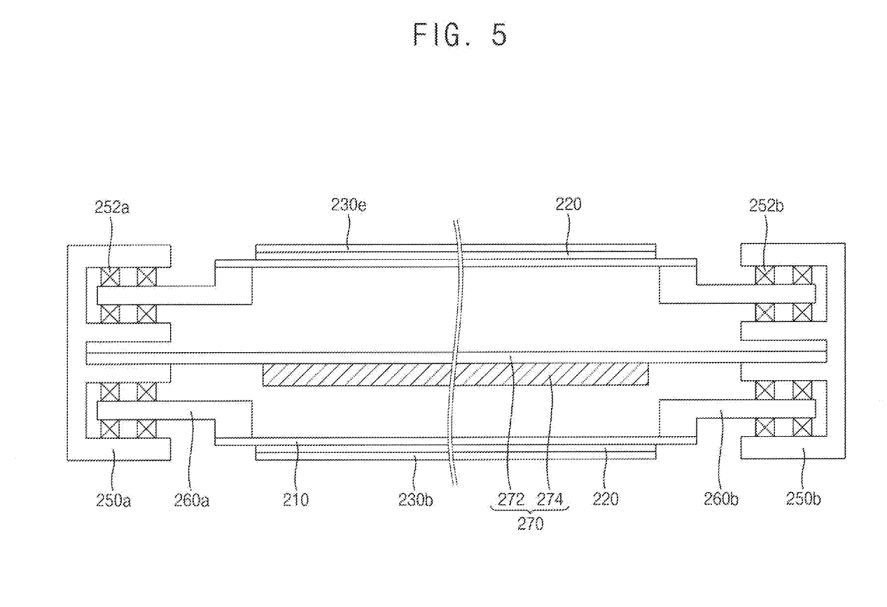

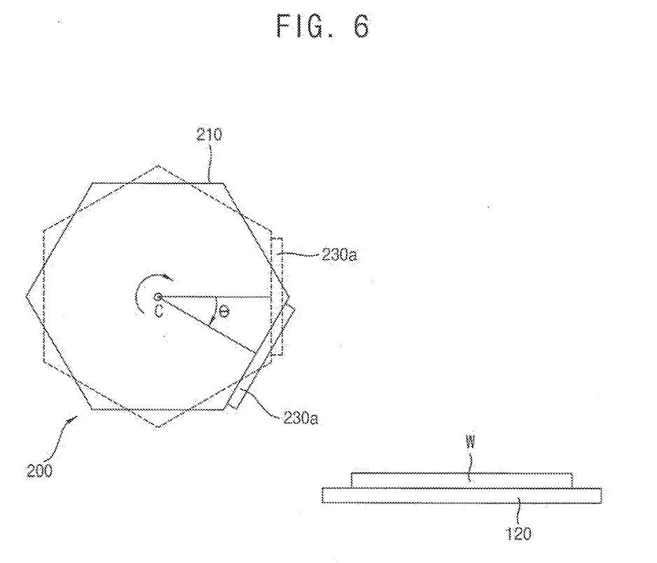

FIG. 1 is a perspective view illustrating a sputtering apparatus in accordance with example embodiments. FIG. 2 is a plan view illustrating the sputtering apparatus of FIG. 1. FIG. 3 is a perspective view illustrating a turret-type target assembly of the sputtering apparatus of FIG. 1. FIG. 4 is a cross-sectional view taken along the line A-A′ in FIG. 3. FIG. 5 is a cross-sectional view taken along the line B-B′ in FIG. 3. FIG. 6 is a cross-sectional view illustrating a rotation operation of the turret-type target assembly of FIG. 3.

Referring to FIGS. 1 to 6, a sputtering apparatus 100 may include a deposition chamber 110, a substrate holder 120 disposed within the deposition chamber 110 and configured to support a substrate, and at least one turret-type target assembly 200, 202 including a plurality of targets mounted on outer surfaces thereof to perform a sputtering process. The at least one turret-type target assembly 200, 202 is rotatable about a longitudinal axis.

In example embodiments, the deposition chamber 110 may be a sealed space in which a deposition is performed on a substrate. The deposition chamber 110 may be a radio frequency (RF) sputtering deposition chamber in which a physical vapor deposition (PVD) process using an RF power source may be performed.

The substrate holder 120 may be disposed within the chamber 110 to support the substrate. For example, the substrate holder 120 may include a circular plate-shaped lower electrode that serves as a susceptor for supporting a semiconductor wafer W thereon. The lower electrode may be supported by a support member such that the lower electrode is movable in upward and downward directions. Accordingly, the substrate may be supported on the lower electrode of the substrate holder 120. A surface of the substrate on which a layer is deposited may be referred to as a film-deposited surface of the substrate.

Additionally, the lower electrode of the substrate holder 120 may be installed to be able to rotate about a central axis of the substrate holder 120. The lower electrode may rotate during a deposition process to rotate the wafer W about a central axis of the wafer W. The central axis of the wafer W may be aligned with the central axis of the substrate holder 120. As the substrate holder 120 rotates, sputtered particles may be distributed more evenly on the wafer (W).

In example embodiments, the sputtering apparatus 100 may include a gas supply 130 configured to supply a gas into the chamber 110. The gas supply 130 may supply an inert sputtering gas into the chamber 110 through a first gas valve (not illustrated). The inert sputtering gas may include, e.g., argon (Ar) or nitrogen (N₂). A mass flow controller (MFC) 132 may be interposed between the gas supply 130 and the chamber 110 to control a flow rate of the inert sputtering gas.

In some embodiments, the inert sputtering gas may impact a target (for example, a magnesium-oxide (MgO) target), thereby causing particles of the target material to be ejected from the target and to be deposited as a desired layer (for example, magnesium-oxide layer) on a wafer (W).

Alternatively, a reaction gas may be introduced into the chamber 110 through a second gas valve (not illustrated). The reaction gas may react chemically with particles from the target material to form a desired deposition material. For example, an oxygen gas may be used with a magnesium target to deposit a magnesium-oxide layer on the wafer W.

A gas exhaust port 142 may be provided in a bottom portion of the chamber 110, and a gas exhaust unit 140 may be connected to the gas exhaust port through a gas exhaust line. The gas exhaust unit 140 may include a vacuum pump (not shown) to control a pressure of the chamber 110 so that the processing space of the chamber 110 may be depressurized to a desired vacuum level.

In example embodiments, the sputtering apparatus 100 may include one or more RF power supplies 310, 312 to supply an RF power to the target. The number of RF power supplies 310, 312 may be the same as the number of turret-type target assemblies 200, 202, and there may be a one-to-one correspondence between the RF power supplies 310, 312 and the turret-type target assemblies 200, 202. The RF power supplies 310 and 312 may provide a high frequency RF power to the targets of the turret-type target assemblies 200 and 202, respectively. The RF power supply 310, 312 may be located outside of the chamber 110 and may be coupled to the corresponding targets of the respective turret-type target assembly 200, 202. The RF power may range from about 400 kHz to about 40 MHz. In an embodiment, the RF power may range from about 10 MHz to about 40 MHz.

Additionally, the sputtering apparatus 100 may include a bias power supply 300 to supply an RF bias power. The bias power supply 300 may be coupled to the lower electrode of the substrate holder 120 such that the particles separated from the target may be accelerated toward the wafer W. For example, the RF bias power may range from about 10 MHz to about 20 MHz.

A plurality of the turret-type target assemblies 200, 202 may be located over the wafer W at an upper space in the chamber 110. A first turret-type target assembly 200 and a second turret-type target assembly 202 may be arranged to face each other with the substrate holder 120 between the first and second turret-type target assemblies 200 and 202. The first turret-type target assembly 200 may be installed in a first sidewall of the chamber 110, and a second turret-type target assembly 202 may be installed in a second sidewall of the chamber 110. The first and second turret-type target assemblies 200 and 202 may be installed in the first and second sidewalls of the chamber 110. For example, as illustrated in FIG. 3, the first turret-type target assembly 200 may be attached to the first sidewall of the chamber 110 through fixing supports 250a and 250b, respectively. Although not shown, the second turret-type target assembly 202 may be attached similarly to the second sidewall of the chamber 110, where the second sidewall is opposite the first sidewall.

Alternatively, the first and second turret-type target assemblies 200 and 202 may be installed to be movable towards or away from each other while the substrate holder 120 is interposed between the first and second turret-type target assemblies 200 and 202. The first turret-type target assembly 200 may be movable in a space between the first sidewall of the chamber 110 and the substrate holder 120, and the second turret-type target assembly 202 may be movable in a space between the second sidewall of the chamber 110 and the substrate holder 120.

When viewed in a plan view, while the sputtering process is performed, the first turret-type target assembly 200 may be positioned to be spaced apart from the central axis of the substrate holder 120 by a first distance S1, and the second turret-type target assembly 202 may be positioned to be spaced apart from the central axis of the substrate holder 120 by a second distance S2. In some embodiments, when viewed in a plan view, the first turret-type target assembly 200 and the second turret-type target assembly 202 may be spaced apart from the substrate holder 120 so as to not vertically overlap the substrate holder 120.

In example embodiments, the sputtering apparatus 100 may further include at least one shutter that operatively blocks a certain area. The shutter may be in open or closed position during sputtering, and the open or closed position of the shutter may shield the first and second turret-type target assemblies 200 and 202.

The shutter may include a first target shutter 400 between the first turret-type target assembly 200 and the substrate holder 120 and a second target shutter 402 between the second turret-type target assembly 202 and the substrate holder 120. The first and second target shutters 400 and 402 may block a material from moving towards the first and second turret-type target assemblies 200 and 202, to thereby prevent the material from being sputtered onto the target.

Further, the shutter may further include a wafer shutter (not illustrated) disposed on the substrate holder 120. The wafer shutter may block the substrate holder 120 from sputtered material.

Hereinafter, the first and second turret-type target assemblies 200, 202 will be explained in detail, with reference to the first turret-type target assembly 200. The second turret-type target assembly 202 may be substantially the same as or similar to the first turret-type target assembly 200, and any further repetitive explanation concerning the second turret-type target assembly 202 will be omitted.

As illustrated in FIGS. 3 to 5, in example embodiments, the first turret-type target assembly 200 may include a plurality of targets 230a, 230b, 230c, 230d and 230e (also referred to herein as targets 230) mounted around the longitudinal axis and adapted to operatively rotate by a predetermined angle about the longitudinal axis such that any one of the targets 230 may be off-axis aligned with respect to a film-deposited surface of the wafer W. Similarly, the second turret-type target assembly 202 may include a plurality of targets 232a, 232b, 232c, 232d and 232e (also referred to herein as targets 232) mounted around the longitudinal axis of the second turret-type target assembly 202 and adapted to operatively rotate by a predetermined angle about the longitudinal axis such that any one of the targets 232 may be off-axis aligned with respect to a film-deposited surface of the wafer W. In some embodiments, the longitudinal axis of each of the first and second turret-type target assemblies 200 and 202 may not be vertically aligned with a central axis of the wafer W, and may not vertically overlap the wafer W.

The first and second turret-type target assemblies 200 and 202 may be located at a higher vertical level than the wafer W and may be offset from a central axis of the wafer W. For example, when viewed in a plan view, the first and second turret-type target assemblies 200 and 202 may not overlap the wafer W. The targets 230 and 232 of the first and second turret-type target assemblies 200 and 202, respectively, may be off-axis aligned with respect to a film-deposited surface of the substrate. In some embodiments, targets 230 and 232 of the first and second turret-type target assemblies 200 and 202, respectively, may be located outside a perimeter of the wafer W, and at least one of the targets 230, 232 from each of the first and second turret-type target assemblies 200 and 202 may face the wafer W at an oblique angle. In some embodiments, the first and second turret-type target assemblies 200 and 202 may rotate by a predetermined angle about their respective longitudinal axis such that at least one target 230, 232 from each of the first and second turret-type target assemblies 200 and 202 forms an oblique angle with respect to a film-deposited surface of the substrate.

In particular, the first turret-type target assembly 200 may be fixedly attached to the first sidewall of the chamber 110 by first and second fixing supports 250a and 250b. The first turret-type target assembly 200 may include a support body 210 of a polyprism shape (e.g., triangle, quadrilateral, pentagon, hexagon, heptagon, octagon, etc.) extending in a direction and having a plurality of target mounting surfaces. The number of target mounting surfaces may correspond to the polyprism shape. For example, the support body 210 may have a hexagonal prism shape, and the support body 210 may have six target mounting surfaces. In some embodiments, the support body 210 may be hollow.

First and second end portions of the support body 210 may be connected to the first and second fixing supports 250a and 250b by first and second rotational brackets 260a and 260b respectively such that the support body 210 may be able to rotate about the longitudinal axis C, as illustrated in FIG. 4. The support body 210 may be installed such that the extending direction (longitudinal axis) of the support body 210 may be parallel with the film-deposited surface of the wafer W. An end portion of the hollow first rotational bracket 260a may be received in the first fixing support 250a, and may be mounted for rotation about its longitudinal direction by a set of bearings 252a, as illustrated in FIG. 5. Similarly, an end portion of the hollow second rotational bracket 260b may be received in the second fixing support 250b, and may be mounted for rotation about its longitudinal direction by a set of bearings 252b. The first end portion of the support body 210 may be combined with the first rotational bracket 260a by a first fixing member, and the second end portion of the support body 210 opposite to the first end portion may be combined with the second rotational bracket 260b by a second fixing member.

The first rotational bracket 260a may be rotated by a drive mechanism (not illustrated). The drive mechanism may include a pulley drive and a servo motor. Alternatively, in other embodiments, the drive mechanism may include a worm gear driving a worm wheel, a belt driving a pulley wheel, a helical gear, etc. As the first rotational bracket 260a is rotated by the drive mechanism, the support body 210 may rotate about its longitudinal axis C with the rotation of the first rotational bracket 260a.

The first turret-type target assembly 200 may include a backing plate 220 on the target mounting surface of the support body 210. For example, the first turret-type target assembly 200 may include six backing plates 220. A backing plate 220 may be located between the support body and each of the targets 230. Each of the targets 230 may be supported on a respective one of the backing plates 220. For example, each of the targets 230 may be adhered to a corresponding backing plate 220 by metallic bonding. Each of the targets 230 may have a rectangular plate shape, and may have a length substantially the same as or greater than a diameter of the wafer W.

The RF power supply 310 may supply the RF power to the targets 230 through the backing plates 220, and each combination of one of the backing plates 220 and one of the targets 230 may function as a cathode or an anode. The backing plates 220 may be configured to control the temperature of the targets 230 during the sputtering process.

The first turret-type target assembly 200 may further include at least one magnet assembly 270 disposed within the support body 210 to face one of the targets 230 on the target mounting surface. The magnet assembly 270 may include a magnet fixing frame 272 and a magnet unit 274 on the magnet fixing frame 272. The magnet fixing frame 272 may extend in a direction within the support body 210. For example, the fixing frame 272 may extend in a lengthwise direction within the support body 210. The end portions of the magnet fixing frame 272 may be combined with the first and second fixing supports 250a and 250b, respectively. The magnet unit 274 may be fixedly installed on the magnet fixing frame 272 to face any one of the target mounting surfaces. For example, the magnet unit 272 may include a permanent magnet, a magnetron, an electromagnet or a combination thereof. A density of the reactive gas or plasma including active species separated from the target may be enhanced by the magnetic field.

Further, although it is not illustrated in the figures, the first turret-type target assembly 200 may further include a cooling system. The cooling system may circulate a coolant through the support body 210. For example, a coolant may be dispersed throughout a cavity within the support body 210. Accordingly, the coolant may absorb heat generated from the targets 230 during the sputtering process through the backing plate 220, to thereby maintain the temperature of the targets 230. Thus, efficiency of the sputtering process may be improved.

Referring to FIGS. 1 and 4, in example embodiments, the first turret-type target assembly 200 may include five targets 230a, 230b, 230c, 230d and 230e respectively mounted on the five backing plates 220 and one pasting target 240 on a sixth backing plate 220. The first turret-type target assembly 200 may rotate the support body 210 such that any one of the targets 230a, 230b, 230c, 230d and 230e may be aligned at a predetermined angle with respect to the film-deposited surface of the wafer W to be selected as a sputtered target. The first turret-type target assembly 200 may rotate the support body 210 such that the pasting target 240 may be aligned with a predetermined angle with respect to the film-deposited surface of the wafer W to be selected as a sputtered target.

For example, the targets 230a, 230b, 230c, 230d and 230e may include magnesium (Mg), aluminum (Al), magnesium oxide (MgO), aluminum oxide (Al₂O₃), etc. The pasting target 240 may include titanium (Ti), tantalum (Ta), etc. Similarly, the second turret-type target assembly 202 may include five targets 232a, 232b, 232c, 232d and 232e respectively mounted on the five backing plates and one pasting target 242 on a sixth backing plate. Each of the targets 230 and 232 may have a quadrilateral shape (e.g., square, rectangular, etc.), and may have a flat or planar surface. In some embodiments, the flat or planar surface of the targets 230 and 232 may form an oblique angle with respect to a film-deposited surface of the substrate.

Accordingly, the sputtering apparatus 100 may sputter the pasting target 240 to form a Ti pasting layer on at least an inner surface of the deposition chamber 110, thereby reducing contaminants within the deposition chamber 110 for subsequent deposition processes.

As illustrated in FIGS. 4 and 6, the plurality of targets 230a, 230b, 230c, 230d and 230e may be supported on the target mounting surfaces of the support body 210 of the hexagonal prism shape. As shown by arrow, the support body 210 may rotate about the longitudinal axis C to select one of the targets 230 to be sputtered and use the selected target 230 to perform a deposition process. Then, the support body 210 may rotate to select a next one of the remaining targets 230 and used the newly selected target 230 to perform a deposition process.

Initially, one target 230a to be sputtered may be determined, and then, an angle (inclination angle of the target mounting surface with respect to the film deposition surface) of the target 230a with respect to the film deposition surface of the wafer W may be determined. For example, a top surface of the target 230a may have an angle inclined with respect to a top surface of the wafer W. The rotation angle θ of the support body 210 may be determined to adjust the angle of the surface of the target 230a with respect to the film deposition surface of the wafer W. Process conditions may vary whenever a deposition process is performed on each of a plurality of wafers W. Thus, the inclination angle of target surface with respect to the wafer W may be determined to vary accordingly in consideration of the various process conditions.

In example embodiments, the first turret-type target assembly 200 may select one of the plurality of targets 230 to perform a sputtering process. The first turret-type target assembly 200 may be arranged over the substrate holder 120 to be spaced laterally from the substrate holder 120 by the first distance S1. Accordingly, the selected one of the plurality of targets 230 may be off-axis aligned with the film deposition surface of the wafer W. The sputtering apparatus 100 may include the plurality of turret-type target assemblies 200 and 202. The second turret-type target assembly 202 having a plurality of targets 232 may perform the sputtering process concurrently with and similar to the sputtering process performed by the first turret-type target assembly 200.

Thus, a preventive maintenance period (i.e., the time between the performance of preventive maintenance) of the sputtering apparatus 100 may be increased and layer thickness uniformity in a wafer plane may be improved. Additionally, particles within the chamber may be reduced or prevented from being generated, and an overall size of the deposition chamber may be decreased and unit per equipment hour (UPEH) may be increased.

Further, in the off-axis sputtering, the wafer may be settled at an outside range or outside a range of discharge plasma. The off-axis sputtering may reduce effects of the irradiation of high-energy particles generated in an on-axis sputtering configuration where the target and the wafer W are arranged to face each other.

FIG. 7 is a plan view illustrating a sputtering apparatus in accordance with example embodiments. The sputtering apparatus may be substantially the same as or similar to the sputtering apparatus as described with reference to FIGS. 1 and 2, except for the number and an arrangement of the turret-type target assemblies. Thus, same reference numerals will be used to refer to the same or like elements and any further repetitive explanation concerning the above elements will be omitted.

Referring to FIG. 7, a sputtering apparatus 101 may include first to fourth turret-type target assemblies 200, 202, 204 and 206 disposed above a substrate holder 120 within a chamber 110. The first to fourth turret-type target assemblies 200, 202, 204 and 206 may be arranged to surround the substrate holder 120. For example, the first to fourth turret-type target assemblies 200, 202, 204 and 206 may be located at a height above and offset from a center of the substrate holder 120.

In particular, the first turret-type target assembly 200 and the second turret-type target assembly 202 may be arranged to face each other with the substrate holder 120 interposed therebetween. The third turret-type target assembly 204 and the fourth turret-type target assembly 206 may be arranged to face each other with the substrate holder 120 interposed therebetween. The first turret-type target assembly 200 may be installed in a first sidewall of the chamber 110, and the second turret-type target assembly 202 may be installed in a second sidewall of the chamber 110 opposite to the first sidewall. The third turret-type target assembly 204 may be installed in a third sidewall of the chamber 110, and the fourth turret-type target assembly 206 may be installed in a fourth sidewall of the chamber 110 opposite to the third sidewall.

The first turret-type target assembly 200 may be installed in the first sidewall of the chamber 110 through a pair of fixing supports 250a and 250b. The second turret-type target assembly 202 may be installed in the second sidewall of the chamber 110 through a pair of fixing supports 252a and 252b. The third turret-type target assembly 204 may be installed in the third sidewall of the chamber 110 through a pair of fixing supports 254a and 254b. The fourth turret-type target assembly 206 may be installed in the fourth sidewall of the chamber 110 through a pair of fixing supports 256a and 256b.

The first turret-type target assembly 200 may be positioned to be spaced apart from the substrate holder 120 by a first distance S1, the second turret-type target assembly 202 may be positioned to be spaced apart from the substrate holder 120 by a second distance S2, the third turret-type target assembly 204 may be positioned to be spaced apart from the substrate holder 120 by a third distance S3, and the fourth turret-type target assembly 206 may be positioned to be spaced apart from the substrate holder 120 by a fourth distance S4.

In example embodiments, the sputtering apparatus 101 may include first to fourth an RF power supplies 310, 312, 314 and 316 to supply an RF power to each of targets of the first to fourth turret-type target assemblies 200, 202, 204 and 206. The first to fourth RF power supplies 310, 312, 314 and 316 may be located outside of the chamber 110, and each of the first to fourth RF power supplies 310, 312, 314 and 316 may be coupled to a respective one of the first to fourth turret-type target assemblies 200, 202, 204 and 206.

Further, the sputtering apparatus 101 may further include first to fourth target shutters 400, 402, 404 and 406. The first target shutter 400 may operatively block a certain area between the first turret-type target assembly 200 and the substrate holder 120. The second target shutter 402 may operatively block a certain area between the second turret-type target assembly 202 and the substrate holder 120. The third target shutter 404 may operatively block a certain area between the third turret-type target assembly 204 and the substrate holder 120. The fourth target shutter 406 may operatively block a certain area between the fourth turret-type target assembly 206 and the substrate holder 120.

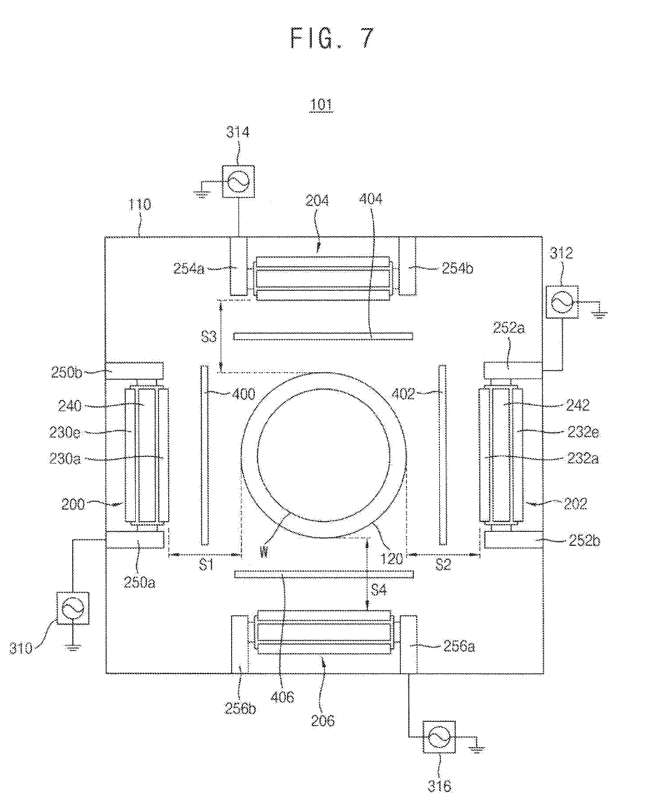

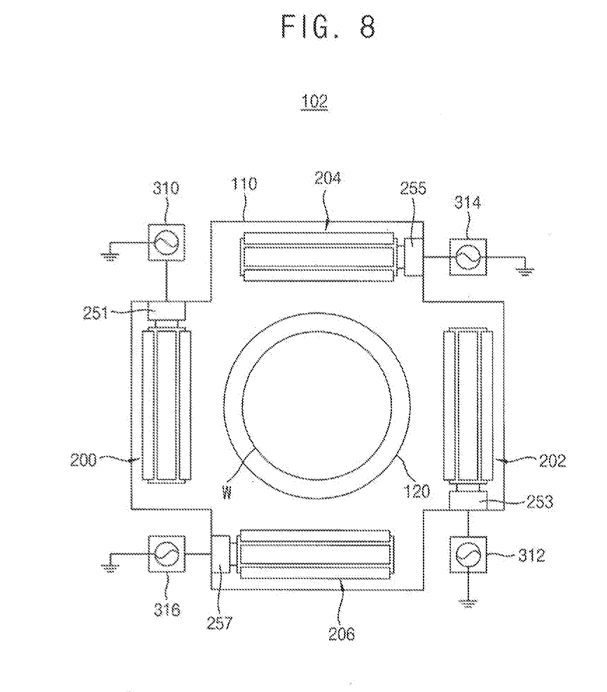

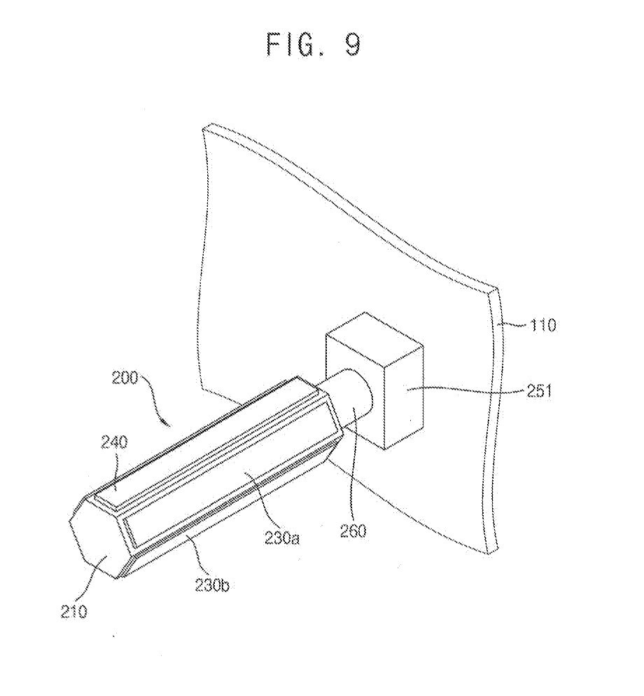

FIG. 8 is a plan view illustrating a sputtering apparatus in accordance with example embodiments. FIG. 9 is a perspective view illustrating a turret-type target assembly of the sputtering apparatus in FIG. 8. The sputtering apparatus may be substantially the same as or similar to the sputtering apparatus as described with reference to FIG. 7, except for a configuration of the turret-type target assembly. Thus, same reference numerals will be used to refer to the same or like elements and any further repetitive explanation concerning the above elements will be omitted.

Referring to FIGS. 8 and 9, a sputtering apparatus 102 may include first to fourth turret-type target assemblies 200, 202, 204 and 206 disposed above a substrate holder 120 within a chamber 110. The first to fourth turret-type target assemblies 200, 202, 204 and 206 may be arranged to surround the substrate holder 120. The first to fourth turret-type target assemblies 200, 202, 204 and 206 may be cantilevered from first to fourth sidewalls of the chamber 110.

The first turret-type target assembly 200 may be installed in the first sidewall of the chamber 110 through one fixing support 251. The second turret-type target assembly 202 may be installed in the second sidewall of the chamber 110 through one fixing support 253. The third turret-type target assembly 204 may be installed in the third sidewall of the chamber 110 through one fixing support 255. The fourth turret-type target assembly 206 may be installed in the fourth sidewall of the chamber 110 through one fixing support 257.

As illustrated in FIG. 9, referring to the first turret-type target assembly 200 as an example, the fixing support 251 may be attached to the first sidewall of the chamber 110, and a first end portion of a support body 210 may be combined with the fixing support 251 such that the support body 210 may be able to rotate about a longitudinal axis C. Accordingly, the support body 210 may be supported at the first end portion, and the support body 210 may extend to protrude from the fixing support 251. The second to fourth turret-type target assembly 202, 204 and 206 may be similarly arranged.

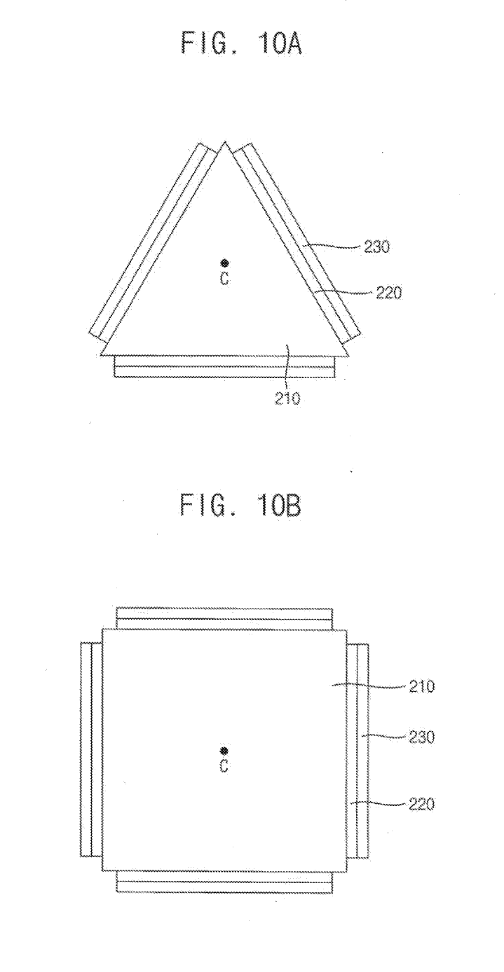

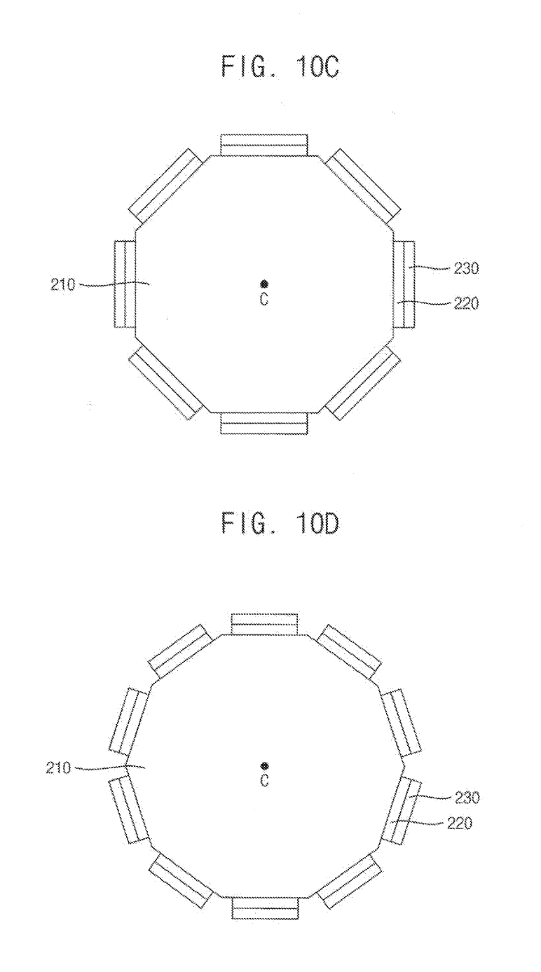

FIGS. 10A to 10D are cross-sectional views illustrating turret-type target assemblies in accordance with example embodiments.

Referring to FIGS. 10A to 10D, a turret-type target assembly may include a support body 210 having various polyprism shapes. The support body 210 may have a cross section shape of, for example, triangle, tetragon, octagon, decagon, etc. However, it may not be limited thereto, and the cross section shape of the support body may have various shapes.

The support body 210 may have a plurality of target mounting surfaces corresponding to the cross section shape. Each of the plurality of targets 230 may be supported on a respective one of target mounting surfaces. A backing plate 220 may be disposed on the target mounting surface, and the target 230 may be disposed on the backing plate 220.

As illustrated in FIG. 10A, when the support body 210 has a cross section shape of a triangle, the turret-type target assembly may have three target mounting surfaces, including two targets 230 and one backing plate 240 respectively mounted thereon. As illustrated in FIG. 10B, when the support body 210 has a cross section shape of a tetragon, the turret-type target assembly may have four target mounting surfaces, including three targets 230 and one backing plate 240 respectively mounted thereon. As illustrated in FIG. 10C, when the support body 210 has a cross section shape of an octagon, the turret-type target assembly may have eight target mounting surfaces, including seven targets 230 and one backing plate 240 respectively mounted thereon. As illustrated in FIG. 10D, when the support body 210 has a cross section shape of a decagon, the turret-type target assembly may have ten target mounting surfaces, including nine targets 230 and one backing plate 240 respectively mounted thereon.

Hereinafter, a method of depositing a layer using the sputtering apparatus in FIG. 1 and a method of manufacturing a magnetoresistive random access memory (MRAM) device using the same will be explained.

FIG. 11 is a flow chart illustrating a method of depositing a layer in accordance with example embodiments. The layer depositing method may be used to deposit a magnesium oxide on a wafer through a sputtering process. However, it should not be construed as limited thereto.

Referring to FIGS. 1 and 11, first and second turret-type target assemblies 200 and 202 may be installed within a deposition chamber 110 of a sputtering apparatus 100, and one of a plurality of targets 230, 232 of each of the first and second turret-type target assemblies 200 and 202 may be determined (S100).

A support body 210 of each of the first and second turret-type target assemblies 200 and 202 may rotate such that any one of the targets 230, 232 may be aligned at a predetermined angle with respect to a film-deposited surface of a wafer W to be selected as a sputtered first target.

Then, the selected first target 230, 232 may be sputtered to deposit a layer on a first wafer (S110). In some embodiments, a first target 230 of the first turret-type target assemblies 200 and a first target 232 of the second turret-type target assemblies 202 may be sputtered to concurrently deposit a layer on a first wafer. The first target 230 and the first target 232 may be collectively referred to as the first target 230, 232.

After the first wafer is loaded onto a substrate holder 120, plasma may be formed on the first target and the first target may be sputtered to deposit the layer on the first wafer. For example, the first targets 230, 232 may be used to perform RF sputtering processes on about 500 to 1,000 wafers respectively.

Then, another one of the plurality of targets 230, 232 may be determined (S120).

Whether or not the first target 230, 232 is consumed may be checked to determine a replacement of the first target 230, 232. If it is determined that the first target 230, 232 needs to be replaced, the support body 210 of each of the first and second turret-type target assemblies 200 and 202 may rotate such that another one of the targets 230, 232 may be aligned at a predetermined angle with respect to a film-deposited surface of a wafer W to be selected as a sputtered second target.

Then, the newly selected second target 230, 232 may be sputtered to deposit a layer on a second wafer (S130).

After the second wafer is loaded onto the substrate holder 120, plasma may be formed on the second target 230, 232 and the second target 230, 232 may be sputtered to deposit the layer on the second wafer. For example, the second target 230, 232 may be used to perform RF sputtering processes on about 500 to 1,000 wafers respectively.

Then, the remaining targets 230, 232 of the plurality of targets 230, 232 mounted on the first and second turret-type target assemblies 200 and 202 may be sequentially used to perform sputtering processes. Accordingly, a preventive maintenance period of the sputtering apparatus may be increased up to five times that of a conventional sputtering apparatus.

In example embodiments, before performing the deposition processes, the support bodies 210, 212 of each of the first and second turret-type target assemblies 200 and 202 may rotate the support bodies 210, 212 such that a pasting targets 240, 242 may be aligned with a predetermined angle with respect to the film-deposited surface of the wafer W to be selected as a sputtered target, and then, the pasting targets 240, 242 may be sputtered to form a Ti pasting layer on at least inner surface of the deposition chamber 110. Thus, contaminants within the deposition chamber 110 may be reduced for subsequent deposition processes.

Hereinafter, a method of manufacturing a semiconductor device using the layer deposition method in FIG. 11 will be explained.

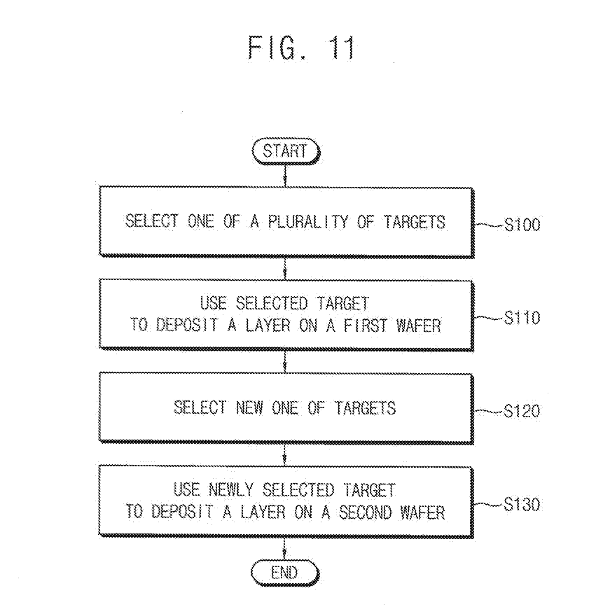

FIGS. 12 to 15 are cross-sectional views illustrating a method of manufacturing an MRAM device in accordance with example embodiments.

Referring to FIG. 12, a first insulating interlayer 12 may be formed on a substrate 10, and a contact plug 20 may be formed through the first insulating interlayer 12 to contact a top surface of the substrate 10.

Although it is not illustrated in the figures, various types of elements, e.g., word lines, transistors, diodes, source/drain layers, source lines, wirings, etc. may be formed on the substrate 10.

The first insulating interlayer 12 may be formed of an oxide, e.g., silicon oxide. The first insulating interlayer 12 may be formed by a chemical vapor deposition (CVD) process, an atomic layer deposition (ALD) process, a spin coating process, etc.

The contact plug 20 may be formed by forming a first opening (not shown) through the first insulating interlayer 12 to expose the top surface of the substrate 10, forming a conductive layer on the exposed top surface of the substrate 10 and the first insulating interlayer 12 to fill the first opening, and planarizing an upper portion of the conductive layer until a top surface of the first insulating interlayer 12 may be exposed.

A lower electrode layer 30, a magnetic tunnel junction (MTJ) layer 40 and an upper electrode layer 50 may be sequentially formed on the first insulating interlayer 12 and the conduct plug 20.

The lower electrode layer 30 may be formed of a metal or a metal nitride.

The MTJ layer 40 may include a first magnetic layer 42, a tunnel barrier layer 44 and a second magnetic layer 46 sequentially stacked.

The first magnetic layer 42 may include a pinning layer, a lower ferromagnetic layer, an anti-ferromagnetic coupling spacer layer and an upper ferromagnetic layer. The pinning layer may be formed of, e.g., FeMn, IrMn, PtMn, MnO, MnS, MnTe, MnF₂, FeF₂, FeCl₂, FeO, CoCl₂, CoO, NiCl₂, NiO, and/or Cr. The lower and upper ferromagnetic layers may be formed of a ferromagnetic material, e.g., Fe, Ni, and/or Co. The anti-ferromagnetic coupling spacer layer may be formed of, e.g., Ru, Ir, and/or Rh.

For example, the tunnel barrier layer 44 may be formed of, e.g., aluminum oxide or magnesium oxide.

In example embodiments, the second magnetic layer 46 may serve as a free layer having a variable magnetization direction. For example, the second magnetic layer 46 may be formed of a ferromagnetic material, e.g., Fe, Ni, and/or Co.

The upper electrode layer 50 may be formed on the MTJ layer 40. The upper electrode layer 50 may serve as a hard mask for etching the MTJ layer 40 and the lower electrode layer 30.

The upper electrode layer 50 may be formed of a metal (e.g., tungsten, titanium, tantalum, etc.) or a metal nitride (e.g., tungsten nitride, titanium nitride, tantalum nitride, etc.). In example embodiments, the upper electrode layer 50 may include at least tungsten.

Hereinafter, a method of depositing a tunnel barrier layer 44 including magnesium oxide will be explained with reference to FIGS. 1 and 12.

Referring again to FIGS. 1 and 12, a wafer (W) including the first magnetic layer 42 formed thereon may be loaded into a deposition chamber 110 of a sputtering apparatus 100, and one of a plurality of targets 230, 232 of each of first and second turret-type target assemblies 200 and 202 may be selected as a target to be sputtered.

A support body 210 of the turret-type target assembly may rotate about a longitudinal axis C to select one of the targets as a sputtered target. In here, the selected target from the plurality of targets may be off-axis aligned with a film-deposited surface of the wafer (W). The target may include magnesium oxide.

Then, the selected target may be sputtered to form the tunnel barrier layer 44 on the wafer (W).

An RF power may be supplied to the target and a bias power may be supplied to a lower electrode of a substrate holder 120 to perform an RF sputtering process. Plasma may be formed on the target and the target may be sputtered to deposit the tunnel barrier layer 44 on the wafer W.

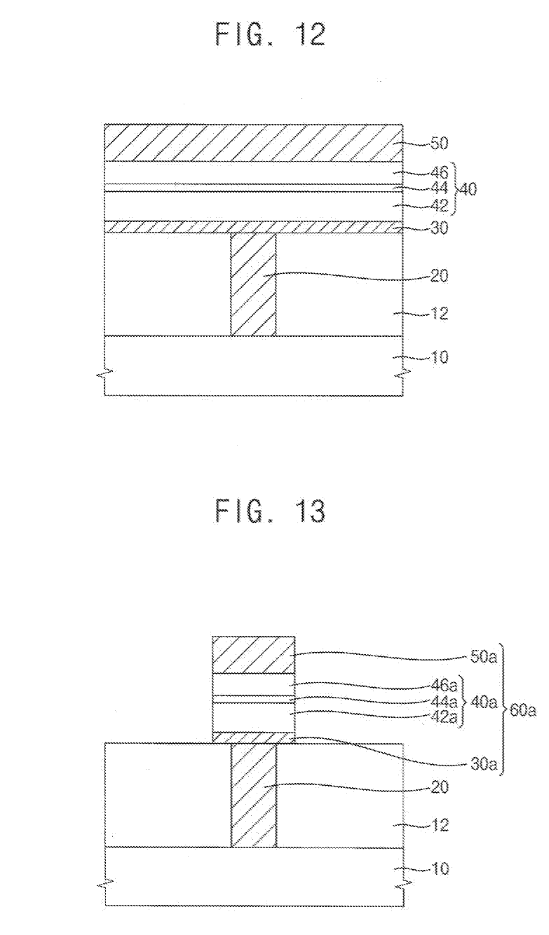

Referring to FIG. 13, an etching mask (not shown) may be formed on the upper electrode layer 50. The upper electrode layer 50 may be etched using the etching mask to form an upper electrode 60a. The etching mask may include a photoresist pattern or an insulation pattern.

The MTJ layer 40 and the lower electrode layer 30 may be sequentially etched using the upper electrode 50a as an etching mask to form a memory structure 60a including a lower electrode 30a, an MTJ structure 40a and the upper electrode 50a sequentially stacked on the contact plug 20.

The MTJ structure 40a may include a first magnetic pattern 42a, a tunnel barrier pattern 44a and a second magnetic pattern 46a sequentially stacked.

The etching process may include a dry etching process, e.g., an ion beam etching, a sputter etching, a radio-frequency (RF) etching, etc. Preferably, the upper electrode layer 50, the MTJ layer 40 and the lower electrode layer 30 may be etched by the ion beam etching process.

Compositions of the memory structure 60a may not be limited to the above, and various modifications may be possible. Further, each of sidewalls of the memory structure 60a may have a vertical slope, as shown in FIG. 13. Alternatively, each of the sidewalls of the memory structure 60a may be inclined relative to a top surface of the substrate 10, and thus a vertical cross-section of the memory structure 60a may have a shape of a trapezoid.

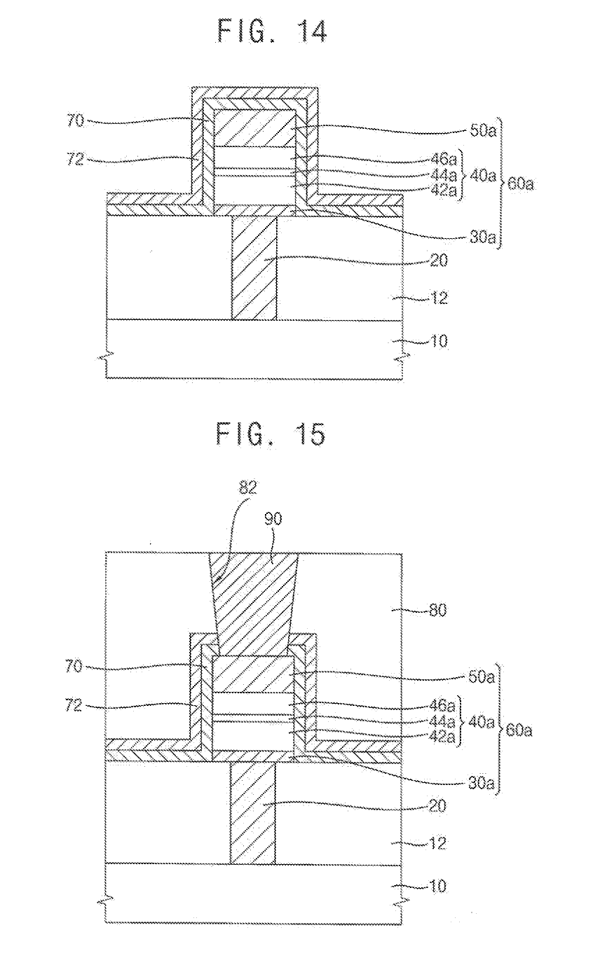

Referring to FIG. 14, a first capping layer 70 may be formed on the first insulating interlayer 12 to cover a surface of the memory structure 60a, including top and side surfaces of the memory structure 60a. A second capping layer 72 may be formed on the first capping layer 70. Accordingly, the first and second capping layers 70 and 72 may be a protective structure that protects the memory structure 60a.

The first and second capping layers 70 and 72 may be formed by a CVD process using plasma. For example, the first and second capping layers 70 and 72 may be formed by a plasma enhanced chemical vapor deposition (PE-CVD) process. Each of the first and second capping layers 70 and 72 may be formed by the CVD process using plasma types that are different from each other.

The first capping layer 70 may directly contact the surface of the memory structure 60a, so that the surface of the memory structure 60a may be damaged by plasma during forming the first capping layer 70. Thus, preferably, the first capping layer 70 may be formed while reducing the plasma damage of the surface of the memory structure 60a.

The second capping layer 72 may have a compactness greater than a compactness of the first capping layer 70 so that the second capping layer 72 may protect the memory structure 60a during performance of subsequent processes. That is, the second capping layer 72 may prevent magnetic materials in the memory structure 60a from being deteriorated due to a thermal process, penetration of chemicals, etc.

For example, each of the first and second capping layers 70 and 72 may be formed of, e.g., silicon nitride, silicon oxynitride, SiCN, SiOCN, aluminum nitride, etc.

Referring to FIG. 15, a second insulating interlayer 80 may be formed on the second capping layer 72 to cover the memory structure 60a.

The second insulating interlayer 80 may be formed of silicon oxide. In example embodiments, an upper surface of the second insulating interlayer 80 may be planarized so as to be flat.

A wiring structure 90 may be formed through the second insulating interlayer 80 and the first and second capping layers 70 and 72 to be electrically connected to the upper electrode 50a.

Particularly, the second insulating interlayer 80 and the first and second capping layers 70 and 72 may be partially etched to form a trench 82 exposing an upper surface of the upper electrode 50a. A barrier layer may be formed on an inner wall and a bottom of the trench 82, and a metal layer may be formed on the barrier layer to fill the trench 82. The metal layer and the barrier layer may be planarized until the upper surface of the second insulating interlayer 80 may be exposed to form the wiring structure 90. The barrier layer may be formed of, e.g., titanium, titanium nitride, tantalum, tantalum nitride, etc. The metal layer may be formed of, e.g., tungsten, copper, aluminum, etc.

The MRAM device according to example embodiments may be used for a memory in various types of electronic devices, e.g., mobile devices, memory cards, computers, etc.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A sputtering method, comprising:
placing a substrate in a chamber configured to provide a space where a deposition process is performed on the substrate;
supporting the substrate within the chamber using a substrate holder; and
performing a sputtering process using a turret-type target assembly located over the substrate,
wherein the turret-type target assembly includes a plurality of targets mounted thereon and adapted to operatively rotate by a predetermined angle about a longitudinal axis such that at least one of the plurality of targets is off-axis aligned with respect to a film-deposited surface of the substrate.

2. The sputtering method of claim 1, wherein the turret-type target assembly comprises a support body of a cross-sectional polyprism shape and has a plurality of target mounting surfaces, and
wherein the support body is rotatable about the longitudinal axis.

3. The sputtering method of claim 2, wherein the longitudinal axis of the support body is parallel with the film-deposited surface of the substrate.

4. The sputtering method of claim 2, wherein the turret-type target assembly comprises a plurality of backing plates,
wherein each of the plurality of backing plates corresponds to one of the plurality of target mounting surfaces of the support body, and
wherein each of the plurality of targets is supported on a corresponding one of the plurality of backing plates.

5. The sputtering method of claim 1, wherein the turret-type target assembly comprises at least one magnet assembly disposed therein to face one of the plurality of targets.

6. The sputtering method of claim 5, wherein the at least one magnet assembly is fixedly installed to face the at least one target mounting surface.

7. The sputtering method of claim 1, wherein the turret-type target assembly is arranged to be spaced laterally from the substrate holder.

8. The sputtering method of claim 1, wherein the turret-type target assembly and at least a second turret-type target assembly are arranged around the substrate holder.

9. The sputtering method of claim 1, further comprising an RF power supply to supply an RF power to the plurality of targets.

10. The sputtering method of claim 1, wherein each of the plurality of targets comprises magnesium oxide.

11. A sputtering method, comprising:
placing a substrate in a deposition chamber;
supporting the substrate within the deposition chamber using a substrate holder; and
performing a sputtering process using at least one turret-type target assembly located over the substrate,
wherein the at least one turret-type target assembly includes a plurality of targets mounted on outer surfaces thereof and adapted to operatively rotate by a predetermined angle about a longitudinal axis such that at least one of the plurality of targets is off-axis aligned with respect to a film-deposited surface of the substrate.

12. The sputtering method of claim 11, wherein the at least one turret-type target assembly comprises a support body of a polyprism shape and has a plurality of target mounting surfaces.

13. The sputtering method of claim 11, wherein the at least one turret-type target assembly comprises at least one magnet assembly disposed therein to face one of the plurality of targets.

14. The sputtering method of claim 11, wherein the at least one turret-type target assembly is arranged to be spaced laterally from the substrate holder.

15. The sputtering method of claim 11, wherein each of the plurality of targets comprises magnesium oxide.

16. A sputtering method, comprising:
placing a substrate in a deposition chamber;
supporting the substrate within the deposition chamber using a substrate holder; and
performing a sputtering process using a turret-type target assembly located above the substrate,
wherein the turret-type target assembly comprises a support body having a plurality of target mounting surfaces, a plurality of targets each mounted on a corresponding one of the plurality target mounting surfaces,
wherein the turret-type target assembly does not overlap the substrate when viewed in a plan view, and
wherein the turret-type target assembly is adapted to rotate by a predetermined angle about a longitudinal axis of the turret-type target assembly such that at least one of the plurality of targets faces a film-deposited surface of the substrate at an oblique angle.

17. The sputtering method of claim 16, wherein the turret-type target assembly comprises a magnet assembly disposed therein to face the plurality of targets.

18. The sputtering method of claim 16, wherein the turret-type target assembly is arranged to be spaced laterally from a center of the substrate holder.

19. The sputtering method of claim 16, wherein the longitudinal axis of the support body is parallel with the film-deposited surface of the substrate.

20. The sputtering method of claim 16, wherein each of the plurality of targets comprises magnesium oxide.
